(19) United States
(12) Patent Application Publication
(10) Pub. No.: US 2025/0069861 A1
(43) Pub. Date: Feb. 27, 2025

(54) MAGNETIC ELEMENT ASSEMBLY AND SUBSTRATE PROCESSING APPARATUS INCLUDING THE SAME

(71) Applicant: SAMSUNG ELECTRONICS CO., LTD., Suwon-si (KR)

(72) Inventors: Myeongsoo Shin, Suwon-si (KR); Donghyeon Na, Suwon-si (KR); Kyung-Sun Kim, Suwon-si (KR); Jaebin Kim, Suwon-si (KR); Myoung Soo Park, Suwon-si (KR); Jong In Park, Suwon-si (KR); Seungbo Shim, Suwon-si (KR); Jimo Lee, Suwon-si (KR); Woongjin Cheon, Suwon-si (KR)

(73) Assignee: SAMSUNG ELECTRONICS CO., LTD., Suwon-si (KR)

(21) Appl. No.: 18/440,554

(22) Filed: Feb. 13, 2024

(30) Foreign Application Priority Data
Aug. 21, 2023 (KR) 10-2023-0108936

(51) Int. Cl. H01J 37/32

(52) U.S. Cl. CPC H01J 37/32669; H01J 37/32642

(57) ABSTRACT

A magnetic element assembly includes a magnetic member having a circular ring shape or an arc shape, and at least one focusing member made of a ferromagnetic material, connected to the magnetic member, and configured to adjust distribution of a magnetic force in a peripheral space, where the at least one focusing member includes a connection portion connected to the magnetic member and at least one focusing portion extending downward from the connection portion.

### CROSS-REFERENCE TO RELATED APPLICATION

This application is based on and claims priority to Korean Patent Application No. 10-2023-0108936, filed on Aug. 21, 2023, in the Korean Intellectual Property Office, the disclosure of which is incorporated herein by reference in its entirety.

### BACKGROUND

The present disclosure relates to a magnetic element assembly and a substrate processing apparatus including the same.

Various processes, such as photolithography, etching, ashing, ion implantation, thin-film deposition, and cleaning, may be performed on a substrate to form desired patterns on the substrate to manufacture semiconductor elements.

Among the processes, an apparatus using plasma may be utilized for dry etching and deposition. In general, in order to form plasma, an electromagnetic field is generated in an internal space of a chamber, and the electromagnetic field excites process gases (which are provided into the chamber) to a plasma state.

Plasma may refer to an ionized gaseous state made by ions, electrons, radicals, or the like. Plasma may be created by implementing very high temperatures, an intense electric field, or a high-frequency electromagnetic field. A semiconductor element manufacturing process may be performed using plasma. The process may be performed as ion particles contained in plasma collide with the substrate. During the processing process, the substrate may be heated by plasma.

### SUMMARY

Example embodiments provide a magnetic element assembly and a substrate processing apparatus including the same, which are capable of effectively processing a substrate by controlling a state of plasma.

Additional aspects will be set forth in part in the description which follows and, in part, will be apparent from the description, or may be learned by practice of the presented embodiments.

According to an aspect of an example embodiment, a magnetic element assembly may include a magnetic member having a circular ring shape or an arc shape, and at least one focusing member made of a ferromagnetic material, connected to the magnetic member, and configured to adjust distribution of a magnetic force in a peripheral space, where the at least one focusing member includes a connection portion connected to the magnetic member and at least one focusing portion extending downward from the connection portion.

According to an aspect of an example embodiment, a magnetic element assembly may include a magnetic member having a circular ring shape or an arc, and a focusing member made of a ferromagnetic material, connected to the magnetic member, and configured to adjust distribution of a magnetic force in a peripheral space, where the focusing member includes a connection portion connected to the magnetic member, an inner focusing portion extending downward from an inner end portion of the connection portion, and an outer focusing portion extending downward from an outer end portion of the connection portion, and where the inner end portion of the connection portion is nearer to a center of the magnetic member than the outer end portion of the connection portion.

According to an aspect of an example embodiment, a substrate processing apparatus may include a chamber including a processing space, a support member in the processing space and configured to support a substrate during a processing procedure, a plasma excitation member configured to apply energy for excitation of plasma to the processing space, and a magnetic element assembly configured to form a magnetic field in the processing space, where the magnetic element assembly includes a magnetic member having a circular ring shape or an arc shape, and a focusing member made of a ferromagnetic material, connected to the magnetic member, and configured to adjust distribution of a magnetic force in a peripheral space, and where the focusing member includes a connection portion connected to the magnetic member and at least one focusing portion extending from an end portion of the connection portion.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a substrate processing apparatus according to one or more example embodiments;

FIG. 2 is a diagram illustrating a magnetic element assembly according to one or more example embodiments;

FIG. 3 is a graph illustrating results in which a magnetic field generated by a magnetic member is focused into a space positioned below the magnetic member according to one or more example embodiments;

FIGS. 4 to 6 are diagrams illustrating positional relationships between a magnetic member and a focusing member according to one or more example embodiments;

FIG. 7 is a diagram illustrating a focusing member according to one or more example embodiments;

FIG. 8 is a diagram illustrating a focusing member according to one or more example embodiments;

FIG. 9 is a graph illustrating results in which a magnetic field, which is generated by a magnetic member, is focused into a space positioned below a magnetic member in accordance with a length of an outer focusing portion and a length of an inner focusing portion, according to one or more example embodiments;

FIGS. 10, 11, and 12 are diagrams illustrating a state in which a focusing member is disposed on the magnetic member according to one or more example embodiments;

FIG. 13 is a diagram illustrating a state in which a focusing member is disposed on the magnetic member according to one or more example embodiments;

FIG. 14 is a diagram illustrating a state in which a focusing member is disposed on the magnetic member according to one or more example embodiments;

FIG. 15 is a diagram illustrating a state in which a focusing member is disposed on the magnetic member according to one or more example embodiments;

FIG. 16 is a diagram illustrating a focusing member according to one or more example embodiments;

FIG. 17 is a diagram illustrating a focusing member according to one or more example embodiments;

FIG. 18 is a diagram illustrating a focusing member according to one or more example embodiments;

FIG. 19 is a diagram illustrating a magnetic element assembly according to one or more example embodiments;

FIG. 20 is a diagram illustrating a focusing member according to one or more example embodiments;

FIG. 21 is a cross-sectional view taken along line A-A in FIG. 20 according to one or more example embodiments;

FIG. 22 is a diagram illustrating a focusing member according to one or more example embodiments;

FIG. 23 is a cross-sectional view taken along line B-B in FIG. 22 according to one or more example embodiments;

FIG. 24 is a diagram illustrating a focusing member according to one or more example embodiments;

FIG. 25 is a cross-sectional view taken along line C-C in FIG. 24 according to one or more example embodiments; and

FIG. 26 is a diagram illustrating a substrate processing apparatus according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

the description may be be omitted to clearly describe the present disclosure, and the same or similar constituent elements may be designated by the same reference numerals throughout the specification.

In addition, a size and thickness of each constituent element illustrated in the drawings are arbitrarily shown for convenience of description, but the present disclosure is not limited thereto. In order to clearly describe several layers and regions, thicknesses thereof are enlarged in the drawings. In the drawings, the thicknesses of some layers and regions are exaggerated for convenience of description.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Throughout the specification, unless explicitly described to the contrary, the word “comprise/include” and variations such as “comprises/includes” or “comprising/including” will be understood to imply the inclusion of stated elements, not the exclusion of any other elements.

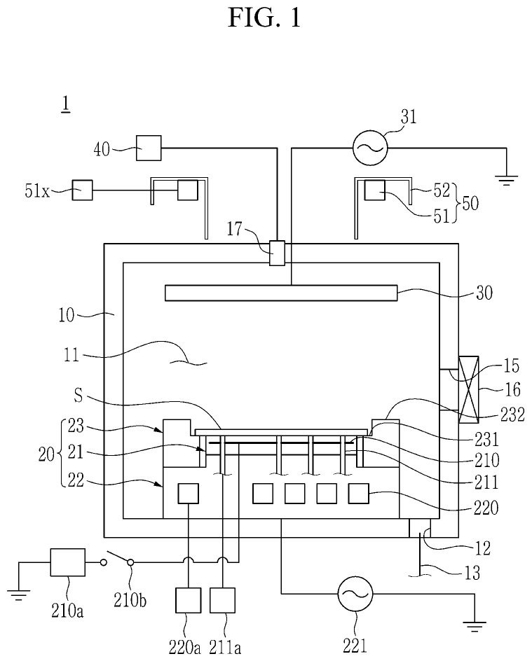

FIG. 1 is a diagram illustrating a substrate processing apparatus according to one or more example embodiments.

With reference to FIG. 1, the substrate processing apparatus 1 according to some embodiments may include a chamber 10, a support member 20, a plasma excitation member 30, a gas supply member 40, and a magnetic element assembly 50.

The substrate processing apparatus 1 processes a substrate S by using plasma. For example, the substrate processing apparatus 1 may perform an etching process, a deposition process, or the like using excited plasma. The substrate S may be a wafer used to manufacture a semiconductor element.

The chamber 10 may provide a processing space 11 in which a process of processing the substrate S is performed. The chamber 10 may have therein the processing space 11 and may have a sealed shape. The chamber 10 may be made of metal. For example, the chamber 10 may be made of aluminum. The chamber 10 may be grounded. An exhaust hole 12 may be formed at one side of the chamber 10. The exhaust hole 12 may be formed in a lower region of the chamber 10. The exhaust hole 12 may be connected to an exhaust line 13. Reaction by-products, which are generated during a processing procedure, and gases, which remain in the internal space of the chamber 10, may be discharged to the outside through the exhaust hole 12. The pressure in the chamber 10 may be lowered to predetermined pressure by an exhaust process.

An opening 15 may be formed at one side of the chamber 10. The opening 15 may be provided as a route through which the substrate S is loaded or unloaded. The opening 15 may be opened or closed by a door 16.

The support member 20 may be disposed in the chamber 10. The support member 20 may be disposed at a lower side of the processing space 11. The support member 20 supports the substrate S. The support member 20 may fix the substrate S using an electrostatic force.

The support member 20 may include a dielectric plate 21, a body 22, and a focus ring 23.

The dielectric plate 21 may be disposed at an upper side of the support member 20. The dielectric plate 21 may have a plate structure having a preset thickness. An outer periphery of the dielectric plate 21 may have a circular shape. The dielectric plate 21 may be made of a dielectric substance. The substrate S may be placed on an upper surface of the dielectric plate 21. An area of the upper surface of the dielectric plate 21 may be smaller than an area of the substrate S. The upper surface of the dielectric plate 21 may have a smaller radius than the substrate S. Therefore, when the substrate S is positioned on the upper surface of the dielectric plate 21, an edge region of the substrate S may be positioned outside the dielectric plate 21.

An internal electrode 210 may be disposed in the dielectric plate 21. The internal electrode 210 may have a shape corresponding to the upper surface of the dielectric plate 21. The internal electrode 210 may be electrically connected to a suction power source 210a. The suction power source 210a may include a direct current power source. A switch 210b may be disposed between the internal electrode 210 and the suction power source 210a. When the switch 210b is turned on, the suction power source 210a may apply a voltage to the internal electrode 210. An electrostatic force may be generated between the internal electrode 210 and the substrate S by the voltage applied by the suction power source 210a, and the electrostatic force allows the dielectric plate 21 to fix the substrate S.

A heat transfer medium supply flow path 211 may be formed in the dielectric plate 21. The heat transfer medium supply flow path 211 may be connected to the upper surface of the dielectric plate 21 and may provide a route along which a heat transfer gas is supplied to the upper surface of the dielectric plate 21. The heat transfer medium supply flow path 211 may be connected to a heat transfer gas storage 211a. The heat transfer gas storage 211a may supply the heat transfer gas to the heat transfer medium supply flow path 211. The heat transfer gas may be an inert gas. For example, the heat transfer gas may be helium (He) or the like. When the heat transfer gas is supplied to the upper surface of the dielectric plate 21 in the state in which the substrate S is fixed onto the upper surface of the dielectric plate 21, the transfer gas may be positioned in a space formed between a bottom surface of the substrate S and the dielectric plate 21. The heat transfer gas may serve as a medium that transfers heat of the substrate S to the support member 20.

The body 22 may be disposed at a lower side of the support member 20. The dielectric plate 21 may be disposed on an upper portion of the body 22. For example, the dielectric plate 21 may be attached to the body 22 by way of a bonding layer. The upper portion of the body 22 may be stepped such that a central region of the upper portion of the body 22 is disposed to be higher than an edge region of the upper portion of the body 22. The central region of the upper portion of the body 22 may have a shape corresponding to a bottom surface of the dielectric plate 21. The dielectric plate 21 may be disposed above the central region of the upper portion of the body 22.

A refrigerant flow path 220 may be formed in the body 22. The refrigerant flow path 220 may provide a route along which a cooling fluid flows in the body 22. For example, the refrigerant flow path 220 may be formed in a spiral shape. In addition, the refrigerant flow path 220 may include ring-shaped flow paths having different radii and the same center. In this case, the ring-shaped flow paths of the refrigerant flow path 220 may be configured to communicate with one another.

The refrigerant flow path 220 may be connected to a refrigerant storage 220a. The refrigerant storage 220a may supply a refrigerant to the refrigerant flow path 220. The refrigerant may cool the body 22 while circulating along the refrigerant flow path 220. As the body 22 is cooled, the dielectric plate 21 and the substrate S may be cooled. That is, the heat of the substrate S may be transferred to the cooled body 22 through the dielectric plate 21.

At least a partial region of the body 22 may be made of metal. For example, the entire body 22 may be made of metal. The body 22 may be made of aluminum. Therefore, the body 22 may serve as an electrode. The lower power source 221 may be electrically connected to a metallic region of the body 22. The lower power source 221 may be provided as a high-frequency power source that generates high-frequency electric power. The lower power source 221 may be provided as a radio frequency (RF) power source. In addition, the lower power source 221 may be excluded, and the metallic region of the body 22 may be grounded.

The focus ring 23 may be disposed in an outer region of an upper portion of the support member 20. The focus ring 23 may be disposed at an outer periphery of the dielectric plate 21. The focus ring 23 may be disposed in an edge region of the upper portion of the body 22. The focus ring 23 may have a ring shape. An upper portion of the focus ring 23 may be stepped such that an outer portion 232 of the upper portion of the focus ring 23 is higher than an inner portion 231 of the upper portion of the focus ring 23. The inner portion 231 of the upper portion of the focus ring 23 may be disposed at a height corresponding to an upper surface of the dielectric plate 21. The inner portion 231 of the upper portion of the focus ring 23 may be disposed below the edge region of the substrate S positioned outside the dielectric plate 21. The outer portion 232 of the upper portion of the focus ring 23 may be disposed to surround the edge region of the substrate S. The focus ring 23 may improve uniformity of density distribution of plasma. During a process of using the focus ring 23, the focus ring 23 may be abraded by contact with the substrate S or an electromagnetic force applied to the focus ring 23. When a degree of abrasion of the focus ring 23 increases, the performance in adjusting the density distribution of plasma deteriorates. Therefore, the focus ring 23 may be replaced after a period of time elapses or the focus ring 23 is used a predetermined number of times.

The plasma excitation member 30 may apply energy for excitation of plasma to the processing space 11. The plasma excitation member 30 may be disposed in the chamber 10. The plasma excitation member 30 may be disposed at an upper side of the processing space 11. The plasma excitation member 30 may be made of a conductive material and have a preset area. The plasma excitation member 30 may be disposed to face the support member 20 in a vertical direction. The plasma excitation member 30 may be electrically connected to an upper power source 31. The upper power source 31 may be provided as a high-frequency power source that generates high-frequency electric power. The upper power source 31 may be provided as an RF power source. In addition, the upper power source 31 may be excluded, and the plasma excitation member 30 may be grounded.

The gas supply member 40 may supply a process gas into the chamber 10. The gas supply member 40 may be connected to a gas inlet 17 disposed at one side of the chamber 10. The gas inlet 17 may be disposed at an upper side of the chamber 10. For example, the gas inlet 17 may be disposed in a central region of an upper surface of the chamber 10. The gas inlet 17 may be provided in the form of a hole, a nozzle, or the like and may provide a route along which the process gas is introduced into the chamber 10. In addition, the gas inlet 17 may be connected to the plasma excitation member 30 such that the process gas is introduced into the processing space 11 via the plasma excitation member 30.

The process gas introduced into the chamber 10 may be excited into plasma by an electric field formed in the chamber 10. Specifically, the process gas may be excited into plasma by a capacitively coupled plasma (CCP) source. The capacitively coupled plasma source may include an upper electrode and a lower electrode. The upper electrode and the lower electrode may be disposed in the chamber 10 and face each other in the vertical direction. When high-frequency electric power is applied to at least one of the upper and lower electrodes, an electromagnetic field may be formed in a space between the upper and lower electrodes, and the process gas supplied into the space may be excited into plasma. According to some embodiments, the upper electrode may be the plasma excitation member 30, and the lower electrode may be the body 22. The high-frequency electric power may be applied to one of the upper and lower electrodes, and the other of the upper and lower electrodes may be grounded. Alternatively, the high-frequency electric power may be applied to both the upper and lower electrodes.

The magnetic element assembly 50 may form a magnetic field in the processing space 11. The magnetic element assembly 50 may be disposed outside the processing space 11.

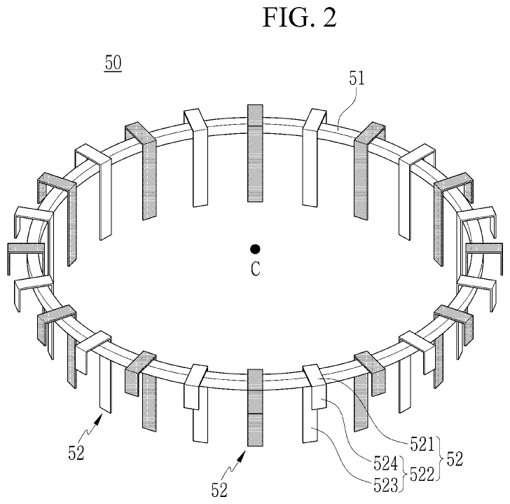

FIG. 2 is a diagram illustrating a magnetic element assembly 50 according to one or more example embodiments.

With reference to FIG. 2, the magnetic element assembly 50 may include a magnetic member 51 and focusing members 52.

The magnetic member 51 may be disposed outside the processing space 11. The magnetic member 51 may be disposed on a circumference defined about an axis that passes through a central region of the processing space 11 and is directed in the vertical direction. The magnetic member 51 may have a circular ring shape, an arc shape made by cutting one side of a circular ring, or the like. Therefore, the magnetic member 51 may include an inner surface directed radially toward a center C, an outer surface directed radially outward with respect to the center C, and upper and lower surfaces positioned between the inner and outer surfaces. A thickness of the magnetic member 51 may be equal to a distance between the inner and outer surfaces. A height of the magnetic member 51 may be equal to a distance between the upper and lower surfaces.

For example, the magnetic member 51 may be disposed to face the processing space 11 in the vertical direction. In addition, an inner periphery of the magnetic member 51 may be larger than an outer periphery of the chamber 10. Therefore, when viewed from above to below, an outer surface of the chamber 10 may be positioned in a space formed inside the inner surface of the magnetic member 51. The magnetic member 51 may generate a magnetic force in a peripheral space. The magnetic member 51 may be an electromagnet. The magnetic member 51 may be electrically connected to an electromagnetic power source 51x. The electromagnetic power source 51x may provide electric power for operating the magnetic member 51. The magnetic member 51 may generate the magnetic force in the peripheral space by an electric power applied by the electromagnetic power source 51x. For example, the magnetic member 51 may generate a magnetic field in the peripheral space such that vectors corresponding to the magnetic force exit the upper portion and enter the lower portion. In addition, the magnetic member 51 may generate a magnetic field in the peripheral space such that vectors corresponding to the magnetic force exit the lower portion and enter the upper portion.

The magnetic member 51 may generate the magnetic field in the processing space 11. The magnetic field applied by the magnetic member 51 may adjust motions of charged particles in the processing space 11. The magnetic field may increase the residence time of electrons in the processing space 11 by changing movement trajectories of the electrons in the processing space 11. Therefore, the heating efficiency and the ionization reaction, which are made by electrons, may be improved, thereby increasing the density of plasma. In addition, the distribution of the magnetic field may be adjusted, such that the plasma density may be adjusted in accordance with the region in the processing space 11.

The focusing members 52 may be connected to the magnetic member 51 and may adjust the distribution of the magnetic force generated in the peripheral space by the magnetic member 51. The focusing members 52 may be provided as a plurality of focusing members 52 disposed in a circumferential direction of the magnetic member 51. In this case, distances between the adjacent focusing members 52 spaced apart from one another may correspond to one another (i.e., the distances between adjacent focusing members 52 may be substantially the same).

Reference is made to a single focusing member 52 below, however such aspects may be applied to some or all focusing members 52. The focusing member 52 may include a region extending from the outer surface of the magnetic member 51 toward an external space. The focusing member 52 may include a region extending from the outer surface of the magnetic member 51 toward the processing space 11. The magnetic member 51 may be disposed to face the processing space 11 in the vertical direction, and the focusing member 52 may include a region extending downward. In this case, a lower end of the focusing member 52 may be disposed below the lower surface of the magnetic member 51. The focusing member 52 may be made of a ferromagnetic material. The focusing member 52 may have relative magnetic permeability (μ) equal to or higher than 500 H/m. A thickness of the focusing member 52 may be adjusted to adjust a focused shape of the magnetic force.

The focusing member 52 may include a connection portion 521 and focusing portions 522.

The connection portion 521 may have a preset length. When the focusing member 52 is connected to the magnetic member 51, a length direction of the connection portion 521 may extend in a radial direction with respect to the center C of the magnetic member 51. A side of the connection portion 521 directed radially toward the center C of the magnetic member 51 may be referred to as an inner side based on the length direction of the connection portion 521. Further, a side of the connection portion 521 directed radially outward with respect to the center C of the magnetic member 51, may be referred to as an outer side. A length of the connection portion 521 may be larger than a thickness of the magnetic member 51. An inner end of the connection portion 521 may be provided to be closer to the center C of the magnetic member 51 than the inner surface of the magnetic member 51 to the center C of the magnetic member 51. An outer end of the connection portion 521 may be disposed to be farther from the center C of the magnetic member 51 than the outer surface of the magnetic member 51 from the center C of the magnetic member 51. The connection portion 521 may have a preset width in the circumferential direction of the magnetic member 51.

The connection portion 521 may be disposed on the upper surface of the magnetic member 51. For example, a bottom surface of the connection portion 521 may contact the upper surface of the magnetic member 51. In addition, the connection portion 521 may be connected to a bottom surface of the magnetic member 51. FIG. 2 illustrates a case in which the connection portion 521 is disposed on the upper surface of the magnetic member 51.

The focusing portion 522 may extend from the connection portion 521 toward the processing space 11. The focusing portion 522 may extend from one end portion of the connection portion 521.

The focusing portion 522 may include an inner focusing portion 523 and an outer focusing portion 524.

The inner focusing portion 523 may extend from the inner end portion of the connection portion 521. The inner focusing portion 523 may extend from the inner end portion of the connection portion 521 toward the processing space 11. The magnetic member 51 may be disposed to face the processing space 11 in the vertical direction, and the inner focusing portion 523 may extend downward from the inner end portion of the connection portion 521. The inner focusing portion 523 may be disposed to be spaced apart from the inner surface of the magnetic member 51. A length of the inner focusing portion 523 may be larger than a height of the magnetic member 51, such that a lower end of the inner focusing portion 523 may be disposed below the lower surface of the magnetic member 51.

The outer focusing portion 524 may extend from the outer end portion of the connection portion 521. The outer focusing portion 524 may extend from the outer end portion of the connection portion 521 toward the processing space 11. The magnetic member 51 may be disposed to face the processing space 11 in the vertical direction, and the outer focusing portion 524 may extend downward from the outer end portion of the connection portion 521. The outer focusing portion 524 may be disposed to be spaced apart from the outer surface of the magnetic member 51. A length of the outer focusing portion 524 may be larger than a height of the magnetic member 51, such that a lower end of the outer focusing portion 524 may be disposed below the lower surface of the magnetic member 51. A length of the outer focusing portion 524 may be shorter than a length of the inner focusing portion 523, such that the lower end of the outer focusing portion 524 may be disposed above the lower end of the inner focusing portion 523.

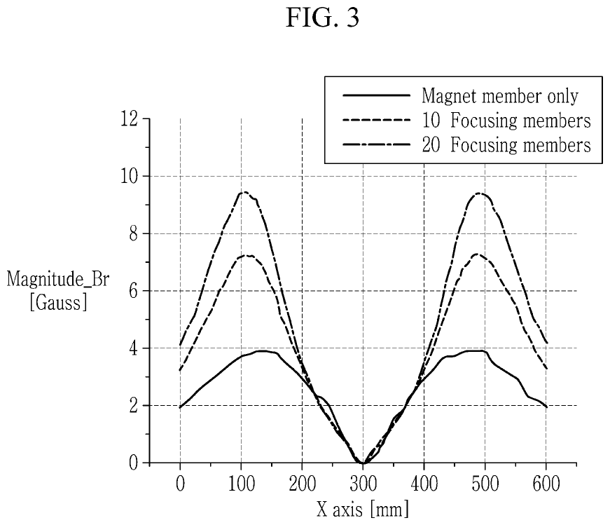

FIG. 3 is a graph illustrating results in which a magnetic field generated by a magnetic member is focused into a space positioned below the magnetic member according to one or more example embodiments.

The magnetic member 51 having a radius of about 150 mm corresponding to a size of the processing space 11 was used. The focusing member 52 was connected to the magnetic member 51 such that the connection portion 521 was disposed on the upper surface of the magnetic member 51. Further, the measurement was performed in a case in which ten focusing members 52 were disposed on the magnetic member 51, a case in which twenty focusing members 52 were disposed on the magnetic member 51, and a case in which only the magnetic member 51 was present without the focusing member 52. In this case, the intensity of the magnetic field in the region adjacent to the lower end of the magnetic member 51 was measured in consideration of the position of the magnetic member 51 in the substrate processing apparatus 1. In addition, an electromagnet was used as the magnetic member 51, and the intensity of the magnetic field was measured in a state in which the remaining conditions remain the same.

With reference to FIG. 3, it may be ascertained that a larger magnetic field is formed in the space positioned below the magnetic member 51 in the case in which the focusing members 52 are connected to the magnetic member 51 in comparison with the case in which only the magnetic member 51 is used. In addition, it may be ascertained that the magnetic field formed in the space positioned below the magnetic member 51 increases as the number of focusing members 52 connected to the magnetic member 51 increases.

That is, it may be ascertained that the intensity of the magnetic field in the space positioned below the magnetic member 51 is increased as the focusing members 52 adjust the direction of the magnetic force at the periphery of the magnetic member 51.

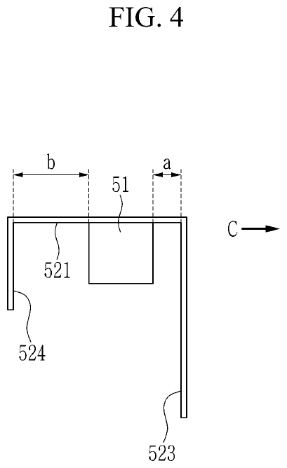

FIGS. 4 to 6 are diagrams illustrating positional relationships between a magnetic member and a focusing member according to one or more example embodiments.

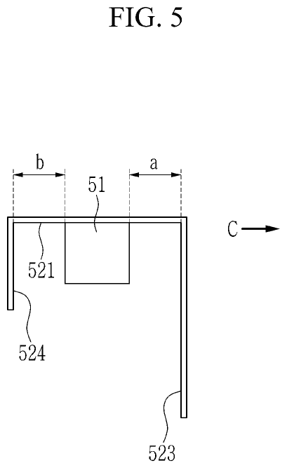

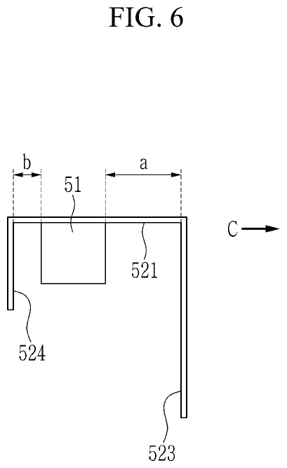

With reference to FIGS. 4 to 6, a spacing distance a between the inner focusing portion 523 and the magnetic member 51 or a spacing distance b between the outer focusing portion 524 and the magnetic member 51 may be adjusted. As illustrated in FIG. 4, the spacing distance a between the inner focusing portion 523 and the magnetic member 51 may be shorter than the spacing distance b between the outer focusing portion 524 and the magnetic member 51. In addition, as illustrated in FIG. 5, the spacing distance a between the inner focusing portion 523 and the magnetic member 51 may correspond to the spacing distance b between the outer focusing portion 524 and the magnetic member 51 (i.e., the spacing distance a may be substantially the same as spacing distance b). In addition, as illustrated in FIG. 6, the spacing distance a between the inner focusing portion 523 and the magnetic member 51 may be longer than the spacing distance b between the outer focusing portion 524 and the magnetic member 51.

The directions and distribution of the magnetic force of the magnetic field generated by the magnetic member 51 may be changed by the inner focusing portion 523 and the outer focusing portion 524. Therefore, the directions, distribution, and the like of the magnetic force at the periphery of the magnetic member 51 may be additionally adjusted by adjusting positions of the magnetic member 51, the inner focusing portion 523, and the outer focusing portion 524.

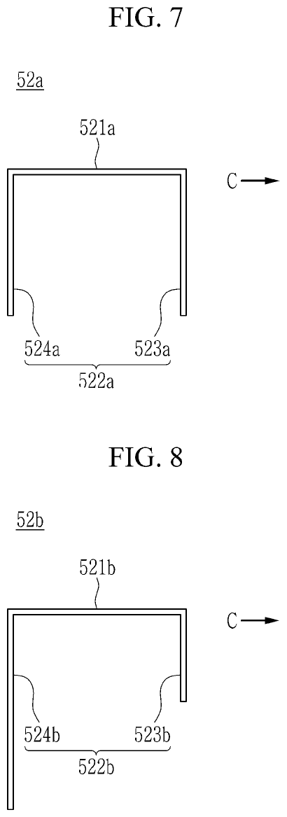

FIG. 7 is a diagram illustrating a focusing member according to one or more example embodiments.

With reference to FIG. 7, the focusing member 52a may include a connection portion 521a and focusing portions 522a.

The focusing member 52a may be made of a ferromagnetic material. The focusing member 52a may have relative magnetic permeability (μ) equal to or higher than 500 H/m.

The connection portion 521a may have a preset length. The connection portion 521a may be provided to extend from the inner surface of the magnetic member 51 to the outer surface of the magnetic member 51. A length of the connection portion 521a may be larger than a thickness of the magnetic member 51. An inner end of the connection portion 521a may be provided to be closer to the center C of the magnetic member 51 than the inner surface of the magnetic member 51 to the center C of the magnetic member 51. An outer end of the connection portion 521a may be disposed to be farther from the center C of the magnetic member 51 than the outer surface of the magnetic member 51 from the center C of the magnetic member 51. The connection portion 521a may have a preset width in the circumferential direction of the magnetic member 51.

The connection portion 521a may be disposed on the upper surface of the magnetic member 51. For example, a bottom surface of the connection portion 521a may contact the upper surface of the magnetic member 51. In addition, the connection portion 521a may be connected to the bottom surface of the magnetic member 51.

The focusing portions 522a may extend from one end portion of the connection portion 521a. The focusing portions 522a may include an inner focusing portion 523a and an outer focusing portion 524a.

The inner focusing portion 523a may extend from the inner end portion of the connection portion 521a. The inner focusing portion 523a may extend from the inner end portion of the connection portion 521a toward the processing space 11. The magnetic member 51 may be disposed to face the processing space 11 in the vertical direction, and the inner focusing portion 523a may extend downward from the inner end portion of the connection portion 521a. The inner focusing portion 523a may be disposed to be spaced apart from the inner surface of the magnetic member 51. A length of the inner focusing portion 523a may be larger than a height of the magnetic member 51, such that a lower end of the inner focusing portion 523a may be disposed below the lower surface of the magnetic member 51.

The outer focusing portion 524a may extend from the outer end portion of the connection portion 521a. The outer focusing portion 524a may extend from the outer end portion of the connection portion 521a toward the processing space 11. The magnetic member 51 may be disposed to face the processing space 11 in the vertical direction, and the outer focusing portion 524a may extend downward from the outer end portion of the connection portion 521a. The outer focusing portion 524a may be disposed to be spaced apart from the outer surface of the magnetic member 51. A length of the outer focusing portion 524a may be larger than a height of the magnetic member 51, such that a lower end of the outer focusing portion 524a may be disposed below the lower surface of the magnetic member 51. A length of the outer focusing portion 524a may correspond to a length of the inner focusing portion 523a, such that the lower end of the outer focusing portion 524a may be disposed at a height corresponding to the lower end of the inner focusing portion 523a.

FIG. 8 is a diagram illustrating a focusing member according to one or more example embodiments.

With reference to FIG. 8, the focusing member 52b may include a connection portion 521b and focusing portions 522b.

The focusing member 52b may be made of a ferromagnetic material. The focusing member 52b may have relative magnetic permeability (μ) equal to or higher than 500 H/m.

The connection portion 521b may have a preset length. The connection portion 521b may be provided to extend from the inner surface of the magnetic member 51 to the outer surface of the magnetic member 51. A length of the connection portion 521b may be larger than a thickness of the magnetic member 51. An inner end of the connection portion 521b may be provided to be closer to the center C of the magnetic member 51 than the inner surface of the magnetic member 51 to the center C of the magnetic member 51. An outer end of the connection portion 521b may be disposed to be farther from the center C of the magnetic member 51 than the outer surface of the magnetic member 51 from the center C of the magnetic member 51. The connection portion 521b may have a preset width in the circumferential direction of the magnetic member 51.

The connection portion 521b may be disposed on the upper surface of the magnetic member 51. For example, a bottom surface of the connection portion 521b may contact the upper surface of the magnetic member 51. In addition, the connection portion 521b may be connected to the bottom surface of the magnetic member 51.

The focusing portions 522b may include an inner focusing portion 523b and an outer focusing portion 524b.

The inner focusing portion 523b may extend from the inner end portion of the connection portion 521b. The inner focusing portion 523b may extend from the inner end portion of the connection portion 521b toward the processing space 11. The magnetic member 51 may be disposed to face the processing space 11 in the vertical direction, and the inner focusing portion 523b may extend downward from the inner end portion of the connection portion 521b. The inner focusing portion 523b may be disposed to be spaced apart from the inner surface of the magnetic member 51. A length of the inner focusing portion 523b may be larger than a height of the magnetic member 51, such that a lower end of the inner focusing portion 523b may be disposed below the lower surface of the magnetic member 51.

The outer focusing portion 524b may extend from the outer end portion of the connection portion 521b. The outer focusing portion 524b may extend from the outer end portion of the connection portion 521b toward the processing space 11. The magnetic member 51 may be disposed to face the processing space 11 in the vertical direction, and the outer focusing portion 524b may extend downward from the outer end portion of the connection portion 521b. The outer focusing portion 524b may be disposed to be spaced apart from the outer surface of the magnetic member 51. A length of the outer focusing portion 524b may be larger than a height of the magnetic member 51, such that a lower end of the outer focusing portion 524b may be disposed below the lower surface of the magnetic member 51. A length of the outer focusing portion 524b may be longer than a length of the inner focusing portion 523b, such that the lower end of the outer focusing portion 524b may be disposed below the lower end of the inner focusing portion 523b.

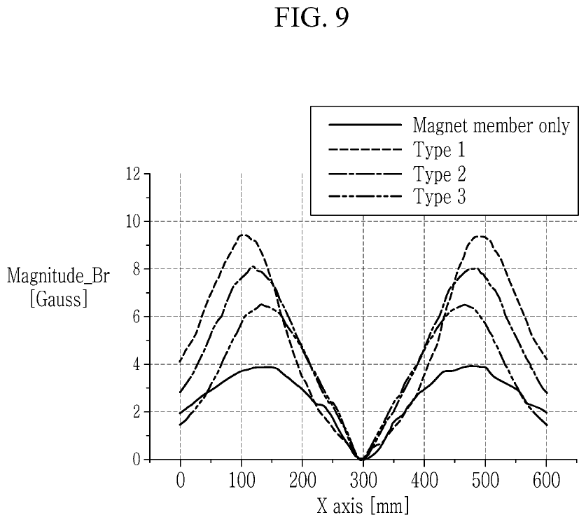

FIG. 9 is a graph illustrating results in which magnetic fields, which are generated by the magnetic member 51, are focused into the space positioned below the magnetic member 51 in accordance with the lengths of the outer focusing portions 524, 524a, and 524b and the lengths of the inner focusing portions 523, 523a, and 523b, according to one or more example embodiments.

Type 1 indicates the case in which the focusing member 52 in FIG. 2 is used, Type 2 indicates the case in which the focusing member 52a in FIG. 7 is used, and Type 3 indicates the case in which the focusing member 52b in FIG. 8 is used. The length of the inner focusing portion 523b of Type 3 corresponds to the length of the outer focusing portion 524 of Type 1, and the length of the outer focusing portion 524b of Type 3 corresponds to the length of the inner focusing portion 523 of Type 1. Further, the length of each of the inner focusing portion 523a and the outer focusing portion 524a of Type 2 corresponds to an approximately intermediate value between the length of the inner focusing portion 523 and the length of the outer focusing portion 524 of Type 1. Further, in all of Type 1, Type 2, and Type 3, the focusing members 52, 52a, and 52b are connected to the magnetic member 51 such that the connection portions 521, 521a, and 521b are disposed on the upper surfaces of the magnetic members 51.

For the comparison, the case in which only the magnetic member 51 is present is also shown. An electromagnet having a radius of about 150 mm was used as the magnetic member 51, and electric power was applied to the magnetic member 51 such that the magnetic force exits the upper portion of the magnetic member 51 and enters the lower portion of the magnetic member 51. The intensity of the magnetic field was measured in a state in which the remaining conditions remain the same, except for the structures of the focusing members 52, 52a, and 52b.

With reference to FIG. 9, it may be ascertained that a larger magnetic field is formed in the space positioned below the magnetic member 51 in case that the focusing members 52, 52a, and 52b of Types 1 to 3 are connected to the magnetic member 51 in comparison with the case in which only the magnetic member 51 is used. In addition, it may be ascertained that the intensity of the magnetic field at a point at which the intensity of the magnetic field is highest is in the order of Type 1, Type 2, and Type 3. In addition, it may be ascertained that the deviation of the intensity of the magnetic field for each region is small in Type 3.

That is, the directions and distribution of the magnetic force at the periphery of the magnetic member 51 may be additionally adjusted by adjusting the lengths of the inner focusing portions 523, 523a, and 523b and the lengths of the outer focusing portions 524, 524a, and 524b of the focusing members 52, 52a, and 52b.

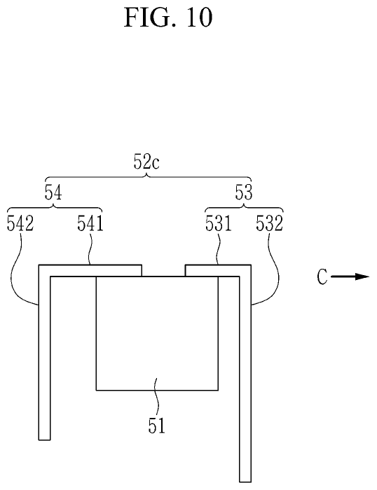

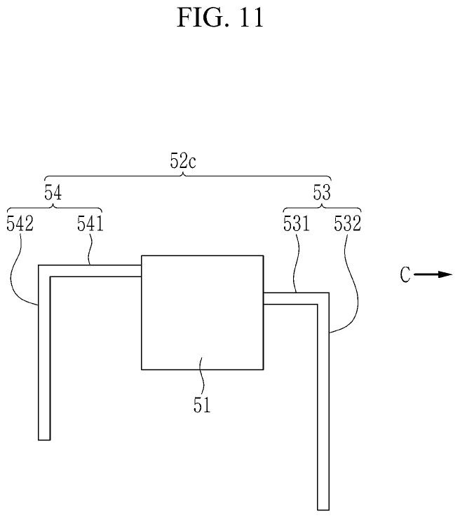

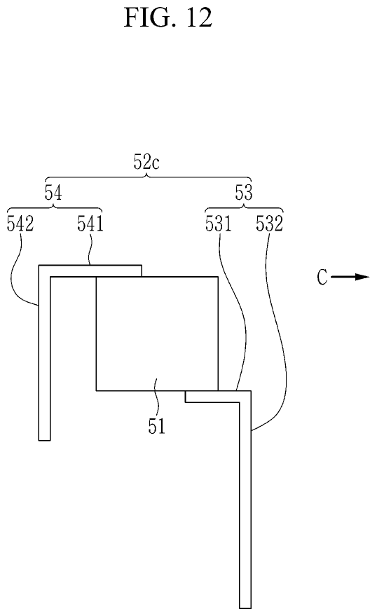

FIGS. 10 to 12 are diagrams illustrating a state in which a focusing member is disposed on the magnetic member according to one or more example embodiments.

With reference to FIGS. 10 to 12, the focusing member 52c may include an inner focusing member 53 and an outer focusing member 54. The focusing member 52c may be made of a ferromagnetic material. The focusing member 52c may have relative magnetic permeability (μ) equal to or higher than 500 H/m.

The inner focusing member 53 may include an inner connection portion 531 and an inner focusing portion 532.

The inner connection portion 531 may have a preset length. When the inner focusing member 53 is connected to the magnetic member 51, a length direction of the inner connection portion 531 may correspond to a radial direction of the magnetic member 51 with respect to the center C of the magnetic member 51. The inner connection portion 531 may include an inner portion and an outer portion. The outer portion of the inner connection portion 531 may extend radially outward with respect to the center C of the magnetic member 51. The outer portion of the inner connection portion 531 may be connected to the magnetic member 51 and may contact the magnetic member 51. For example, the outer portion of the inner connection portion 531 may be disposed on the upper surface of the magnetic member 51. In addition, the outer portion of the inner connection portion 531 may be connected to the inner surface of the magnetic member 51. In addition, the outer portion of the inner connection portion 531 may be connected to the bottom surface of the magnetic member 51. The inner portion of the inner connection portion 531 may be spaced apart from the outer portion of the inner connection portion 531 as well as the magnetic member 51, such that the inner portion does not contact the magnetic member 51.

The inner focusing portion 532 may extend from an inner end portion of the inner connection portion 531. The inner focusing portion 532 may extend from the end portion of the inner connection portion 531 toward the processing space 11. The magnetic member 51 may be disposed to face the processing space 11 in the vertical direction, and the inner focusing portion 532 may extend downward from the end portion of the inner connection portion 531. The inner focusing portion 532 may be disposed to be spaced apart from the inner surface of the magnetic member 51. A lower end of the inner focusing portion 532 may be disposed below the lower surface of the magnetic member 51.

The outer focusing member 54 may include an outer connection portion 541 and an outer focusing portion 542.

The outer connection portion 541 may have a preset length. When the outer focusing member 54 is connected to the magnetic member 51, a length direction of the outer connection portion 541 may correspond to a radially direction with respect to the center C of the magnetic member 51. The outer connection portion 541 may include an inner portion and an outer portion. The inner portion of the outer connection portion 541 may extend radially inward with respect to the center C of the magnetic member 51. The inner portion of the outer connection portion 541 may be connected to the magnetic member 51 and may contact the magnetic member 51. For example, the inner portion of the outer connection portion 541 may be disposed on the upper surface of the magnetic member 51. In addition, the inner portion of the outer connection portion 541 may be connected to the outer surface of the magnetic member 51. In addition, the inner portion of the outer connection portion 541 may be connected to the bottom surface of the magnetic member 51. The outer portion of the outer connection portion 541 may be spaced apart from the inner portion of the outer connection portion 541 as well as the magnetic member 51, such that the outer portion does not contact the magnetic member 51

The outer focusing portion 542 may extend from an end portion of the outer connection portion 541. The outer focusing portion 542 may extend from the end portion of the outer connection portion 541 toward the processing space 11. The magnetic member 51 may be disposed to face the processing space 11 in the vertical direction, and the outer focusing portion 542 may extend downward from the end portion of the outer connection portion 541. The outer focusing portion 542 may be disposed to be spaced apart from the outer surface of the magnetic member 51. A lower end of the outer focusing portion 542 may be disposed below the lower surface of the magnetic member 51. A length of the outer focusing portion 542 may be shorter than a length of the inner focusing portion 532. In addition, a length of the outer focusing portion 542 may correspond to a length of the inner focusing portion 532 (i.e., the length of the outer focusing portion 542 may be substantially the same as the length of the inner focusing portion 532). In addition, a length of the outer focusing portion 542 may be longer than a length of the inner focusing portion 532. The lower end of the outer focusing portion 542 may be disposed above the lower end of the inner focusing portion 532. In addition, the lower end of the outer focusing portion 542 may be disposed below the lower end of the inner focusing portion 532. In addition, the lower end of the outer focusing portion 542 and the lower end of the inner focusing portion 532 may be disposed at heights that correspond to each other (i.e., at heights that are substantially the same).

A position on the focusing member 52c, which is connected to the magnetic member 51, may be adjusted to adjust the magnetic field generated at the periphery of the magnetic member 51 and the focusing member 52c. In addition, the magnetic field generated at the periphery of the magnetic member 51 and the focusing member 52c may be adjusted by adjusting a distance between the inner focusing portion 532 of the focusing member 52c and the inner surface of the magnetic member 51, a length of the inner focusing portion 532, a distance between the outer focusing portion 542 and the outer surface of the magnetic member 51, and a length of the outer focusing portion 542.

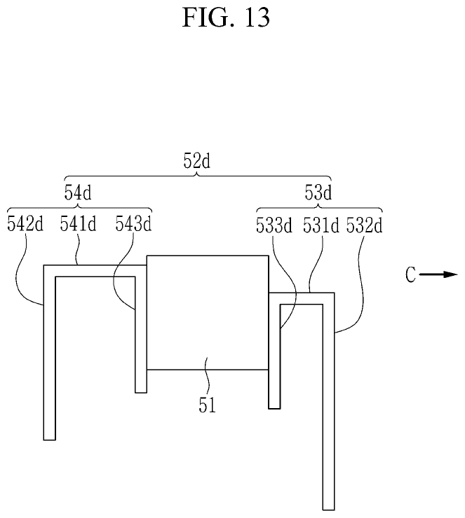

FIG. 13 is a diagram illustrating a state in which a focusing member is disposed on the magnetic member according to one or more example embodiments.

The focusing member 52d may include an inner focusing member 53d and an outer focusing member 54d. The focusing member 52d may be made of a ferromagnetic material. The focusing member 52d may have relative magnetic permeability (μ) equal to or higher than 500 H/m.

The inner focusing member 53d may include an inner connection portion 531d and an inner focusing portions 532d.

The inner connection portion 531d may have a preset length. When the inner focusing member 53d is connected to the magnetic member 51, a length direction of the inner connection portion 531d may correspond to a radial direction with respect to a center C of the magnetic member 51. An inner fastening portion 533d may be formed at an outer end portion of the inner connection portion 531d. The inner fastening portion 533d may extend in a direction parallel to the inner surface of the magnetic member 51. For example, the inner fastening portion 533d may extend downward. The inner fastening portion 533d may be connected to the inner surface of the magnetic member 51. A lower end of the inner fastening portion 533d may be disposed below the lower surface of the magnetic member 51. In addition, the lower end of the inner fastening portion 533d may be disposed above the lower surface of the magnetic member 51.

The inner focusing portion 532d may extend from an inner end portion of the inner connection portion 531d. The inner focusing portion 532d may extend from the inner end portion of the inner connection portion 531d toward the processing space 11. The magnetic member 51 may be disposed to face the processing space 11 in the vertical direction, and the inner focusing portion 532d may extend downward from the inner end portion of the inner connection portion 531d. The inner focusing portion 532d may be disposed to be spaced apart from the inner surface of the magnetic member 51. A lower end of the inner focusing portion 532d may be disposed below the lower surface of the magnetic member 51d.

The outer focusing member 54d may include an outer connection portion 541d and an outer focusing portion 542d.

The outer connection portion 541d may have a preset length. When the outer focusing member 54d is connected to the magnetic member 51, a length direction of the outer connection portion 541d may correspond to a radial direction with respect to a center C of the magnetic member 51. An outer fastening portion 543d may be formed at an inner end portion of the outer connection portion 541d. The outer fastening portion 543d may extend in a direction parallel to the outer surface of the magnetic member 51. For example, the outer fastening portion 543d may extend downward. The outer fastening portion 543d may be connected to the outer surface of the magnetic member 51. A lower end of the outer fastening portion 543d may be disposed below the lower surface of the magnetic member 51. In addition, the lower end of the outer fastening portion 543d may be disposed above the lower surface of the magnetic member 51.

The outer focusing portion 542d may extend from an outer end portion of the outer connection portion 541d. The outer focusing portion 542d may extend from the outer end portion of the outer connection portion 541d toward the processing space 11. The magnetic member 51 may be disposed to face the processing space 11 in the vertical direction, and the outer focusing portion 542d may extend downward from the outer end portion of the outer connection portion 541d. The outer focusing portion 542d may be disposed to be spaced apart from the outer surface of the magnetic member 51. A lower end of the outer focusing portion 542d may be disposed below the lower surface of the magnetic member 51.

A length of the outer focusing portion 542d may be shorter than a length of the inner focusing portion 532d. In addition, a length of the outer focusing portion 542d may correspond to (i.e., be substantially the same as) a length of the inner focusing portion 532d. In addition, a length of the outer focusing portion 542d may be longer than a length of the inner focusing portion 532d. The lower end of the outer focusing portion 542d may be disposed above the lower end of the inner focusing portion 532d. In addition, the lower end of the outer focusing portion 542d may be disposed below the lower end of the inner focusing portion 532d. In addition, the lower end of the outer focusing portion 542d and the lower end of the inner focusing portion 532d may be disposed at heights that correspond to each other (i.e., that are substantially the same as each other).

A position on the focusing member 52d, which is connected to the magnetic member 51, may be adjusted to adjust the magnetic field generated at the periphery of the magnetic member 51 and the focusing member 52d. In addition, the magnetic field generated at the periphery of the magnetic member 51 and the focusing member 52d may be adjusted by adjusting a distance between the inner focusing portion 532d of the focusing member 52d and the inner surface of the magnetic member 51, a length of the inner focusing portion 532d, a distance between the outer focusing portion 542d and the outer surface of the magnetic member 51, and a length of the outer focusing portion 542d.

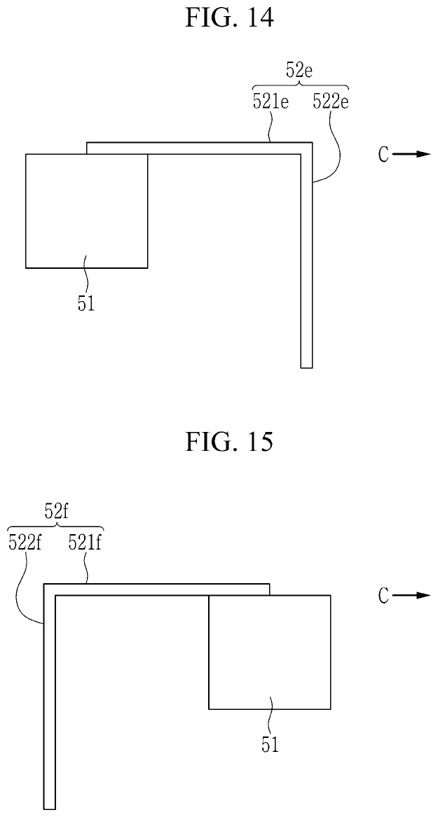

FIG. 14 is a diagram illustrating a state in which a focusing member is disposed on the magnetic member according to one or more example embodiments.

With reference to FIG. 14, the focusing member 52e may include a connection portion 521e and a focusing portion 522e. The focusing member 52e may be made of a ferromagnetic material. The focusing member 52e may have relative magnetic permeability (μ) equal to or higher than 500 H/m.

The connection portion 521e may have a preset length. When the focusing member 52e is connected to the magnetic member 51, a length direction of the connection portion 521e may correspond to a radial direction with respect to the center C of the magnetic member 51. The connection portion 521e may include an inner portion and an outer portion. The outer portion of the connection portion 521e may extend radially outward with respect to the center C of the magnetic member 51. The outer portion of the connection portion 521e may be connected to the magnetic member 51 and may contact the magnetic member 51. For example, the outer portion of the connection portion 521e may be disposed on the upper surface of the magnetic member 51. In addition, the outer portion of the connection portion 521e may be connected to the inner surface of the magnetic member 51. In addition, the outer portion of the connection portion 521e may be connected to the bottom surface of the magnetic member 51. The inner portion of the connection portion 521e may be spaced apart from the outer portion of the connection portion 521e as well as the magnetic member 51, such that the inner portion does not contact the magnetic member 51. FIG. 14 illustrates a case in which the connection portion 521e is disposed on the upper surface of the magnetic member 51.

The focusing portion 522e may extend from an end portion of the connection portion 521e. The focusing portion 522e may extend from the end portion of the connection portion 521e toward the processing space 11. The magnetic member 51 may be disposed to face the processing space 11 in the vertical direction, and the focusing portion 522e may extend downward from the end portion of the connection portion 521e. The focusing portion 522e may be disposed to be spaced apart from the inner surface of the magnetic member 51. A lower end of the focusing portion 522e may be disposed below the lower surface of the magnetic member 51.

FIG. 15 is a diagram illustrating a state in which a focusing member is disposed on the magnetic member according to one or more example embodiments.

With reference to FIG. 15, the focusing member 52f may include a connection portion 521f and a focusing portion 522f. The focusing member 52f may be made of a ferromagnetic material. The focusing member 52f may have relative magnetic permeability (μ) equal to or higher than 500 H/m.

The connection portion 521f may have a preset length. When the focusing member 52f is connected to the magnetic member 51, a length direction of the connection portion 521f may correspond to a radial direction with respect to the center C of the magnetic member 51. The connection portion 521f may include an inner portion and an outer portion. The inner portion of the connection portion 521f may extend radially inward with respect to the center C of the magnetic member 51. The inner portion of the connection portion 521f may be connected to the magnetic member 51 and may contact the magnetic member 51. For example, the inner portion of the connection portion 521f may be disposed on the upper surface of the magnetic member 51. In addition, the inner portion of the connection portion 521f may be connected to the outer surface of the magnetic member 51. In addition, the inner portion of the connection portion 521f may be connected to the bottom surface of the magnetic member 51. The outer portion of the connection portion 521f may be spaced apart from the inner portion of the connection portion 521f as well as the magnetic member 51, such that the outer portion does not contact the magnetic member 51. FIG. 15 illustrates a case in which the connection portion 521f is disposed on the upper surface of the magnetic member 51.

The focusing portion 522f may extend from an end portion of the connection portion 521f. The focusing portion 522f may extend from the end portion of the connection portion 521f toward the processing space 11. The magnetic member 51 may be disposed to face the processing space 11 in the vertical direction, and the focusing portion 522f may extend downward from the end portion of the connection portion 521f. The focusing portion 522f may be disposed to be spaced apart from the inner surface of the magnetic member 51. A lower end of the focusing portion 522f may be disposed below the lower surface of the magnetic member 51.

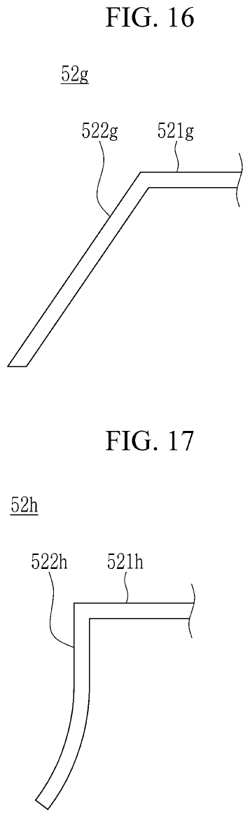

FIG. 16 is a diagram illustrating a focusing member according to one or more example embodiments.

With reference to FIG. 16, the focusing member 52g may include a connection portion 521g and a focusing portion 522g.

The connection portion 521g may have a preset length.

The focusing portion 522g may extend from one end portion of the connection portion 521g. The focusing portion 522g may be inclined with respect to a direction orthogonal to a length direction of the connection portion 521g. The focusing portion 522g may be inclined in a direction opposite to the connection portion 521g based on the direction orthogonal to the length direction of the connection portion 521g. In addition, the focusing portion 522g may be inclined with respect to the connection portion 521g based on the direction orthogonal to the length direction of the connection portion 521g.

In this case, the focusing portion 522g may be the focusing portion 522 in FIG. 2, the focusing portion 522a in FIG. 7, the focusing portion 522b in FIG. 8, the inner focusing portion 532 or the outer focusing portion 542 in FIGS. 10 to 12, the inner focusing portion 532d or the outer focusing portion 542d in FIG. 13, the focusing portion 522e in FIG. 14, or the focusing portion 522f in FIG. 15.

FIG. 17 is a diagram illustrating a focusing member according to one or more example embodiments.

With reference to FIG. 17, the focusing member 52h may include a connection portion 521h and a focusing portion 522h.

The connection portion 521h may have a preset length.

The focusing portion 522h may extend from one end portion of the connection portion 521h. At least a portion of the focusing portion 522h may have a bent structure. For example, at least a portion of the focusing portion 522h may have a curved structure. At least a portion of the focusing portion 522h may have a structure bent in a direction opposite to the connection portion 521h. In addition, at least a portion of the focusing portion 522h may have a structure bent in a direction corresponding to a length direction of the connection portion 521h.

In this case, the focusing portion 522h may be the focusing portion 522 in FIG. 2, the focusing portion 522a in FIG. 7, the focusing portion 522b in FIG. 8, the inner focusing portion 532 or the outer focusing portion 542 in FIGS. 10 to 12, the inner focusing portion 532d or the outer focusing portion 542d in FIG. 13, the focusing portion 522e in FIG. 14, or the focusing portion 522f in FIG. 15.

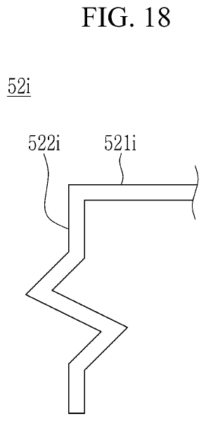

FIG. 18 is a diagram illustrating a focusing member according to one or more example embodiments.

With reference to FIG. 18, the focusing member 52i may include a connection portion 521i and a focusing portion 522i.

The connection portion 521i may have a preset length.

The focusing portion 522i may extend from one end portion of the connection portion 521i. At least a portion of the focusing portion 522i may have a zigzag shape.

In this case, the focusing portion 522i may be the focusing portion 522 in FIG. 2, the focusing portion 522a in FIG. 7, the focusing portion 522b in FIG. 8, the inner focusing portion 532 or the outer focusing portion 542 in FIGS. 10 to 12, the inner focusing portion 532d or the outer focusing portion 542d in FIG. 13, the focusing portion 522e in FIG. 14, or the focusing portion 522f in FIG. 15.

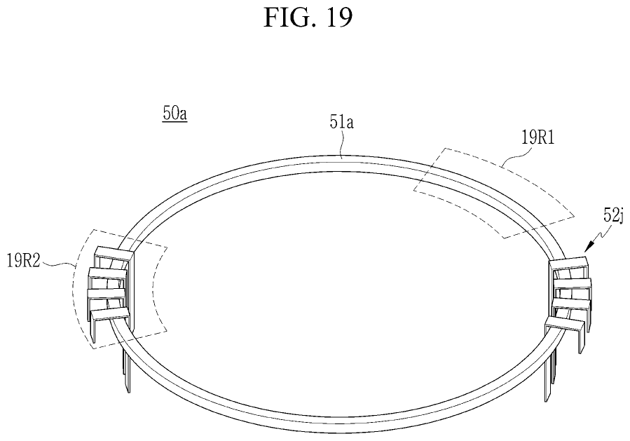

FIG. 19 is a diagram illustrating a magnetic element assembly according to one or more example embodiments.

With reference to FIG. 19, the magnetic element assembly 50a may include a magnetic member 51a and focusing members 52j.

The magnetic member 51a may include aspects similar to the magnetic member 51 of the magnetic element assembly 50 in FIG. 2, and as such, repeated descriptions may be omitted.

The focusing members 52j may be connected to the magnetic member 51a and may adjust the distribution of the magnetic force generated in the peripheral space by the magnetic member 51a. The focusing members 52j may be provided as a plurality of focusing members 52j disposed in a circumferential direction of the magnetic member 51a. In this case, the number of focusing members 52j disposed on the magnetic member 51a of unit length may vary depending on the regions. For example, in first region 19R1, there are zero focusing members. In second region 19R2, there are four focusing members 52j. The first region 19R1 and the second region 19R2 are the same length. Therefore, the distribution of the magnetic field generated in the peripheral space of the magnetic element assembly 50a may be differently adjusted in accordance with the region along the circumferential direction of the magnetic member 51a.

In addition, at least one of the plurality of focusing members 52j may have a structure different from those of the remaining focusing members 52j. For example, at least one of the plurality of focusing members 52j may be one of the focusing member 52 in FIG. 2, the focusing member 52a in FIG. 7, the focusing member 52b in FIG. 8, the focusing member 52c in FIGS. 10 to 12, the focusing member 52d in FIG. 13, the focusing member 52e in FIG. 14, the focusing member 52f in FIG. 15, the focusing member 52g in FIG. 16, the focusing member 52h in FIG. 17, and the focusing member 52i in FIG. 18. One of the remaining focusing members 52j may be one of the focusing member 52 in FIG. 2, the focusing member 52a in FIG. 7, the focusing member 52b in FIG. 8, the focusing member 52c in FIGS. 10 to 12, the focusing member 52e in FIG. 14, the focusing member 52f in FIG. 15, the focusing member 52g in FIG. 16, the focusing member 52h in FIG. 17, and the focusing member 52i in FIG. 18.

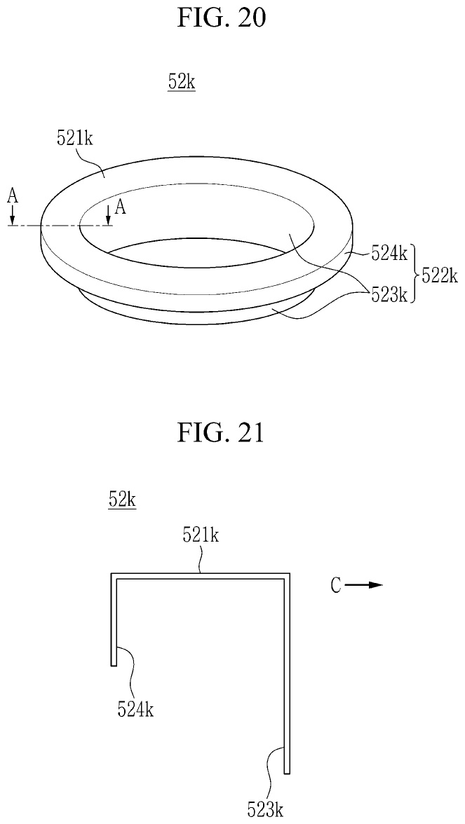

FIG. 20 is a diagram illustrating a focusing member according to one or more example embodiments. FIG. 21 is a cross-sectional view taken along line A-A in FIG. 20 according to one or more example embodiments.

With reference to FIGS. 20 and 21, the focusing member 52k may include a connection portion 521k and focusing portions 522j.

The connection portion 521k may have a shape corresponding to the magnetic member 51 or 51a. For example, the connection portion 521k may have a circular ring shape. In addition, the connection portion 521k may have an arc shape made by cutting one side of a circular ring. A width of the connection portion 521k, which is directed in a radial direction, may be larger than a thickness of the magnetic member 51.

The focusing portion 522k may extend from one end portion of the connection portion 521k.

The focusing portions 522k may include an inner focusing portion 523k and an outer focusing portion 524k.

The inner focusing portion 523k may extend from an inner end portion of the connection portion 521k. The inner focusing portion 523k may extend from the inner end portion of the connection portion 521k toward the processing space 11. The magnetic member 51 or 51a may be disposed to face the processing space 11 in the vertical direction, and the inner focusing portion 523k may extend downward from the inner end portion of the connection portion 521k. When the connection portion 521k is disposed on the upper surface of the magnetic member 51, the inner focusing portion 523k may be disposed to be spaced apart from the inner surface of the magnetic member 51 or 51a. A length of the inner focusing portion 523k may be larger than a height of the magnetic member 51, such that a lower end of the inner focusing portion 523k may be disposed below the lower surface of the magnetic member 51 or 51a. In addition, the inner focusing portion 523k may have the same structure as the focusing portion 522g in FIG. 16, the focusing portion 522h in FIG. 17, or the focusing portion 522i in FIG. 18.

The outer focusing portion 524k may extend from an outer end portion of the connection portion 521k. The outer focusing portion 524k may extend from the outer end portion of the connection portion 521k toward the processing space 11. The magnetic member 51 or 51a may be disposed to face the processing space 11 in the vertical direction, and the outer focusing portion 524k may extend downward from the outer end portion of the connection portion 521k. When the connection portion 521k is disposed on the upper surface of the magnetic member 51 or 51a, the outer focusing portion 524k may be disposed to be spaced apart from the outer surface of the magnetic member 51 or 51a. A length of the outer focusing portion 524k may be larger than a height of the magnetic member 51 or 51a, such that a lower end of the outer focusing portion 524k may be disposed below the lower surface of the magnetic member 51 or 51a. A length of the outer focusing portion 524k may be shorter than a length of the inner focusing portion 523k. In addition, a length of the outer focusing portion 524k may be longer than a length of the inner focusing portion 523k. In addition, a length of the outer focusing portion 524k and a length of the inner focusing portion 523k may correspond to each other (i.e., may be substantially the same as each other). In addition, the outer focusing portion 524k may have the same structure as the focusing portion 522g in FIG. 16, the focusing portion 522h in FIG. 17, or the focusing portion 522i in FIG. 18.

In addition, the connection portion 521k may be connected to the lower surface of the magnetic member 51 or 51a.

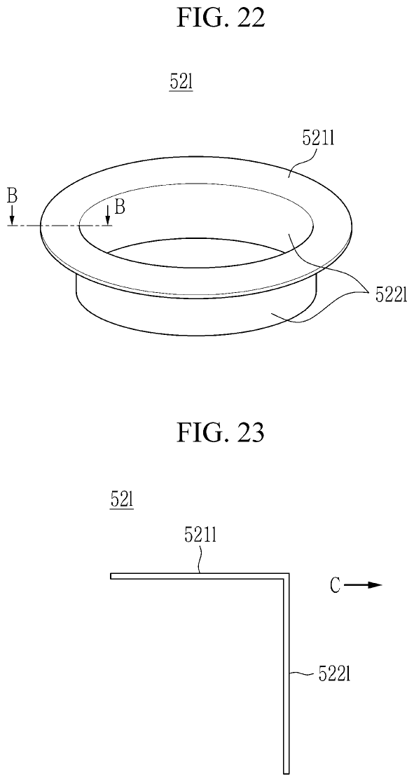

FIG. 22 is a diagram illustrating a focusing member according to one or more example embodiments. FIG. 23 is a cross-sectional view taken along line B-B in FIG. 22 according to one or more example embodiments.

With reference to FIGS. 22 and 23, the focusing member 521 may include a connection portion 521l and a focusing portion 522l.

The connection portion 521l has a shape corresponding to the magnetic member 51 or 51a. For example, the connection portion 521l may have a circular ring shape. In addition, the connection portion 521l may have an arc shape made by cutting one side of a circular ring.

An outer portion) of the connection portion 521l, which is disposed at a side directed radially outward with respect to the center C of the magnetic member 51 or 51a, may be connected to the magnetic member 51 or 51a. For example, the outer portion of the connection portion 521l may be disposed on the upper surface of the magnetic member 51 or 51a. In addition, the outer portion of the connection portion 521l may be connected to the inner surface of the magnetic member 51 or 51a. In addition, the outer portion of the connection portion 521l may be connected to the bottom surface of the magnetic member 51 or 51a.

The focusing portion 522l may extend from an inner end portion of the connection portion 521l. The focusing portion 522l may extend from the inner end portion of the connection portion 521l toward the processing space 11. The magnetic member 51 or 51a may be disposed to face the processing space 11 in the vertical direction, and the focusing portion 522l may extend downward from the inner end portion of the connection portion 521l. When the connection portion 521l is connected to the magnetic member 51 or 51a, the focusing portion 522l may be disposed to be spaced apart from the inner surface of the magnetic member 51 or 51a. A lower end of the focusing portion 522l may be disposed below the lower surface of the magnetic member 51 or 51a. In addition, the focusing portion 522l may have the same structure as the focusing portion 522g in FIG. 16, the focusing portion 522h in FIG. 17, or the focusing portion 522i in FIG. 18.

In addition, the connection portion 521l may be connected to the lower surface of the magnetic member 51 or 51a or the inner surface of the magnetic member 51 or 51a.

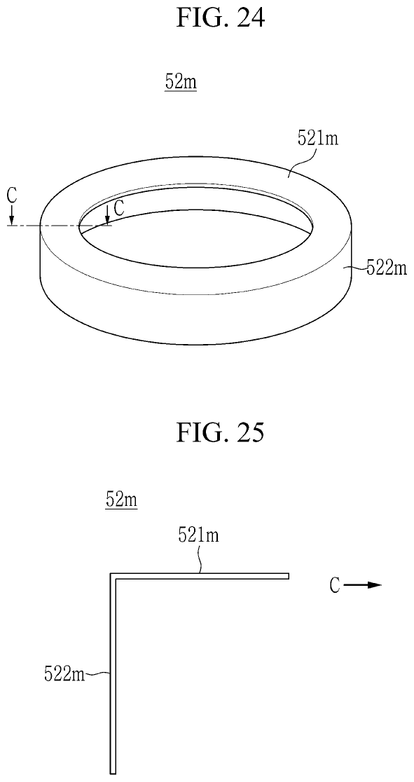

FIG. 24 is a diagram illustrating a focusing member according to one or more example embodiments. FIG. 25 is a cross-sectional view taken along line C-C in FIG. 24 according to one or more example embodiments.

With reference to FIGS. 24 and 25, the focusing member 52m may include a connection portion 521m and a focusing portion 522m.

The connection portion 521m may have a shape corresponding to the magnetic member 51 or 51a. For example, the connection portion 521m may have a circular ring shape. In addition, the connection portion 521m may have an arc shape made by cutting one side of a circular ring.

An inner portion of the connection portion 521m that extends radially inward with respect to the center C of the magnetic member 51 or 51a may be connected to the magnetic member 51 or 51a and may contact the magnetic member 51 or 51a. For example, the inner portion of the connection portion 521m may be disposed on the upper surface of the magnetic member 51 or 51a. In addition, the inner portion of the connection portion 521m may be connected to the outer surface of the magnetic member 51 or 51a. In addition, the inner portion of the connection portion 521m may be connected to the bottom surface of the magnetic member 51 or 51a. The outer portion of the connection portion 521m may be spaced apart from the inner portion of the connection portion 521m as well as the magnetic member 51 or 51a, such that the outer portion does not contact the magnetic member 51 or 51a.

The focusing portion 522m may extend from an outer end portion of the connection portion 521m. The focusing portion 522m may extend from the outer end portion of the connection portion 521m toward the processing space 11. The magnetic member 51 or 51a may be disposed to face the processing space 11 in the vertical direction, and the focusing portion 522m may extend downward from the outer end portion of the connection portion 521m. When the connection portion 521m is connected to the magnetic member 51 or 51a, the focusing portion 522m may be disposed to be spaced apart from the outer surface of the magnetic member 51 or 51a. A lower end of the focusing portion 522m may be disposed below the lower surface of the magnetic member 51 or 51a. In addition, the focusing portion 522m may have the same structure as the focusing portion 522g in FIG. 16, the focusing portion 522h in FIG. 17, or the focusing portion 522i in FIG. 18.

In addition, the connection portion 521m may be connected to the lower surface of the magnetic member 51 or 51a or the outer surface of the magnetic member 51 or 51a.

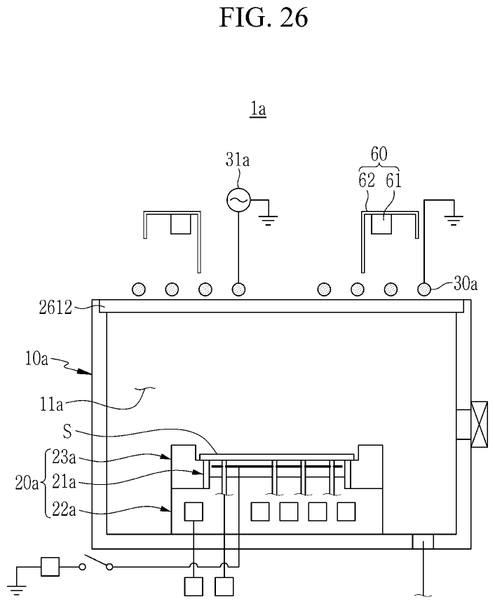

FIG. 26 is a diagram illustrating a substrate processing apparatus according to one or more example embodiments.

With reference to FIG. 26, the substrate processing apparatus 1a may include a chamber 10a, a support member 20a, a plasma excitation member 30a, the gas supply member 40, and a magnetic element assembly 60.

The substrate processing apparatus 1a may process a substrate S using plasma.

At least a partial region of an upper wall 2612 of the chamber 10a may be made of a dielectric material. The remaining structure of the chamber 10a may include aspects similar to that of the chamber 10 of the substrate processing apparatus 1 in FIG. 1, and as such, repeated descriptions may be omitted.

The support member 20a may be disposed in the chamber 10a. The support member 20a may support the substrate S.

The support member 20a may include a dielectric plate 21a, a body 22a, and a focus ring 23a.

The dielectric plate 21a may include aspects similar to the dielectric plate 21 of the substrate processing apparatus 1 in FIG. 1, and as such, repeated descriptions may be omitted.

The lower power source 221 of the substrate processing apparatus 1 in FIG. 1 may not be connected to the body 22a. The remaining structure of the body 22a may include aspects similar to that of the body 22 of the substrate processing apparatus 1 in FIG. 1, and as such, repeated descriptions may be omitted.

The focus ring 23a may include aspects similar to the focus ring 23 of the substrate processing apparatus 1 in FIG. 1, and as such, repeated descriptions may be omitted.

The plasma excitation member 30a may apply energy for excitation of plasma to the processing space 11a. The plasma excitation member 30a may have an antenna structure. The plasma excitation member 30a may be disposed outside the processing space 11a. The plasma excitation member 30a may be disposed adjacent to an upper surface of the upper wall 2612 of the chamber 10a. The plasma excitation member 30a may be disposed to face the processing space 11a with the upper wall 2612 of the chamber 10a interposed therebetween.

The plasma excitation member 30a may be electrically connected to an antenna power source 31a. The antenna power source 31a may be provided as a high-frequency power source that generates high-frequency electric power. The antenna power source 31a may be provided as an RF power source. The plasma excitation member 30a may generate electromagnetic waves by way of electric power provided by the antenna power source 31a. The gas in the processing space 11a may be excited to plasma by the electromagnetic waves generated by the plasma excitation member 30a.

The magnetic element assembly 60 may generate a magnetic field in the processing space 11a. The magnetic element assembly 60 may be disposed outside the processing space 11a.

The magnetic element assembly 60 may include a magnetic member 61 and a focusing member 62.

The magnetic member 61 may include aspects similar to the magnetic member 51 or 51a, and as such, repeated descriptions may be omitted.

The focusing member 62 may include aspects similar to the focusing members 52, 52a, 52b, 52c, 52e, 52f, 52g, 52h, 52i, 52j, 52k, 52k, and 52m, and as such, repeated descriptions may be omitted.

According to some embodiments of the present disclosure, the magnetic element assembly and the substrate processing apparatus including the same are provided, which are capable of effectively processing a substrate by controlling a state of plasma.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A magnetic element assembly comprising:
a magnetic member having a circular ring shape or an arc shape; and
at least one focusing member made of a ferromagnetic material, connected to the magnetic member and configured to adjust distribution of a magnetic force in a peripheral space,
wherein the at least one focusing member further comprises:
a connection portion connected to the magnetic member; and
at least one focusing portion extending downward from the connection portion.

2. The magnetic element assembly of claim 1, wherein the at least one focusing member comprises a plurality of focusing members provided on the magnetic member.

3. The magnetic element assembly of claim 2, wherein spacing distances between adjacent focusing members of the plurality of focusing members are substantially the same.

4. The magnetic element assembly of claim 2, wherein the plurality of focusing members comprise a first number of focusing members in a first region of the magnetic member and a second number of focusing members in a second region of the magnetic member, the second number of focusing members being different from the first number of focusing members.

5. The magnetic element assembly of claim 2, wherein at least one of the plurality of focusing members has a structure that is different from a structure of at least one remaining focusing members of the plurality of focusing members.

6. The magnetic element assembly of claim 1, wherein a lower end of the at least one focusing portion is below a lower surface of the magnetic member.

7. The magnetic element assembly of claim 1, wherein the connection portion is on an upper surface of the magnetic member,
wherein the at least one focusing portion comprises:
an inner focusing portion extending downward from an inner end portion of the connection portion; and
an outer focusing portion extending downward from an outer end portion of the connection portion, and
wherein the inner end portion of the connection portion is nearer to a center of the magnetic member than the outer end portion of the connection portion.

8. The magnetic element assembly of claim 7, wherein a lower end of the outer focusing portion is above a lower end of the inner focusing portion.

9. The magnetic element assembly of claim 7, wherein the inner focusing portion is spaced apart from an inner surface of the magnetic member that is radially inward with respect to a center of the magnetic member.

10. The magnetic element assembly of claim 7, wherein the outer focusing portion is spaced apart from an outer surface of the magnetic member that is radially outward with respect to a center of the magnetic member.

11. The magnetic element assembly of claim 1, wherein the connection portion comprises:
an inner portion contacting the magnetic member and extending radially outward with respect to a center of the magnetic member; and
an outer portion spaced apart from the magnetic member, and
wherein the at least one focusing portion extends downward from the outer portion of the connection portion.

12. The magnetic element assembly of claim 1, wherein the connection portion comprises:
an inner portion contacting the magnetic member and extending radially inward with respect to a center of the magnetic member; and
an outer portion spaced apart from the magnetic member, and
wherein the at least one focusing portion extends downward from the outer portion of the connection portion.

13. The magnetic element assembly of claim 1, wherein the at least one focusing portion is inclined with respect to a direction orthogonal to a length direction of the connection portion.

14. The magnetic element assembly of claim 1, wherein at least a portion of the at least one focusing portion has a bent structure.

15. The magnetic element assembly of claim 1, wherein at least a portion of the at least one focusing portion has a zigzag shape.

16. The magnetic element assembly of claim 1, wherein the connection portion has a circular shape or an arc shape corresponding to the shape of the magnetic member.

17. A magnetic element assembly comprising:
a magnetic member having a circular ring shape or an arc; and
a focusing member made of a ferromagnetic material, connected to the magnetic member, and configured to adjust distribution of a magnetic force in a peripheral space,
wherein the focusing member comprises:
a connection portion connected to the magnetic member;
an inner focusing portion extending downward from an inner end portion of the connection portion; and
an outer focusing portion extending downward from an outer end portion of the connection portion, and
wherein the inner end portion of the connection portion is nearer to a center of the magnetic member than the outer end portion of the connection portion.

18. A magnetic element assembly comprising:
a magnetic member having a circular ring shape or an arc shape; and
a plurality of focusing members made of a ferromagnetic material, connected to the magnetic member, and configured to adjust distribution of a magnetic force in a peripheral space, and
wherein each of the plurality of focusing members comprises:
a connection portion connected to the magnetic member;
an inner focusing portion extending downward from an inner end portion of the connection portion; and
an outer focusing portion extending downward from an outer end portion of the connection portion, and
wherein a lower end of at least one focusing portion of the plurality of focusing portions is below a lower surface of the magnetic member.

19. The magnetic element assembly of claim 18, wherein a lower end of the outer focusing portion is above a lower end of the inner focusing portion.

20. The magnetic element assembly of claim 18, wherein the inner focusing portion is spaced apart from an inner surface of the magnetic member that is radially inward with respect to a center of the magnetic member, and
wherein the outer focusing portion is spaced apart from an outer surface of the magnetic member that is radially outward with respect to a center of the magnetic member.
